(19) United States
(12) Patent Application Publication
(10) Pub. No.: US 2022/0276329 A1
(43) Pub. Date: Sep. 1, 2022

(54) INTELLIGENT INSTRUMENT VERIFICATION SYSTEM AND METHOD

(71) Applicant: 38TH RESEARCH INSTITUET, CHINA ELECTRONICS TECHNOLOGY GROUP CORPORATION, Hefei (CN)

(72) Inventors: Guoqiang SUN, Hefei (CN); Fangning TIAN, Hefei (CN); Jianjun SU, Hefei (CN); Wenqing TONG, Hefei (CN); Yifeng BAI, Hefei (CN)

(21) Appl. No.: 17/745,843

(22) Filed: May 16, 2022

Related U.S. Application Data
(63) Continuation of application No. PCT/CN2021/115605, filed on Aug. 31, 2021.

(30) Foreign Application Priority Data
Sep. 10, 2020 (CN) 202010947542.5

(51) Int. Cl. G01R 35/00

(52) U.S. Cl. CPC G01R 35/005

(57) ABSTRACT

Disclosed are an intelligent instrument verification system and method. The intelligent instrument verification system includes an automatic verification system, a reference instrument group and a communication control interface. The automatic verification system is connected to an instrument to be verified through the communication control interface. The automatic verification system is connected to the reference instrument group through the communication control interface. The reference instrument group is connected to the instrument to be verified through the communication control interface.

### CROSS-REFERENCE TO RELATED APPLICATIONS

This application is a continuation of International Patent Application No. PCT/CN2021/115605, filed on Aug. 31, 2021, which claims the benefit of priority from Chinese Patent Application No. 202010947542.5, filed on Sep. 10, 2020. The content of the aforementioned applications, including any intervening amendments thereto, is incorporated herein by reference in its entirety.

### TECHNICAL FIELD

This application relates to instrument verification, and more particularity to an intelligent instrument verification system and method.

### BACKGROUND

The verification and periodic test of instruments is necessary for the obtaining of accurate and qualified measurement data. Regarding the large calibration stations, instruments are required to experience periodic verification to ensure that they are qualified and valid. In the traditional measurement and verification process, a verification test platform is manually constructed with reference to the calibration standard of a certain type of instruments, and the instruments are tested sequentially according to verification items. Moreover, the data record and analysis are often performed manually. Thus, the traditional metrological verification struggles with poor efficiency, larger labor consumption and cumbersome digital search and storage. In view of this, an intelligent instrument verification system and method are provided herein.

### SUMMARY

In order to enable the automatic verification of basic and general metrological instruments, the disclosure provides an intelligent instrument calibration system.

Technical solutions of the disclosure are described as follows.

In a first aspect, this application provides an intelligent instrument verification system, comprising:

an automatic verification system;

a reference instrument group; and

a communication control interface;

wherein the automatic verification system is in bidirectional communication with an instrument to be verified through the communication control interface; the automatic verification system is in bidirectional communication with the reference instrument group through the communication control interface; and the reference instrument group is in bidirectional communication with the instrument to be verified through the communication control interface.

In some embodiments, the automatic verification system comprises a first verification subsystem, a second verification subsystem, a third subsystem, a fourth verification subsystem and a fifth verification subsystem; the first verification subsystem is configured to verify a signal generator; the second verification subsystem is configured to verify a noise-measuring instrument; the third verification subsystem is configured to verify a spectrum analyzer; the fourth verification subsystem is configured to verify a power meter; and the fifth verification subsystem is configured to verify a network analyzer. The five verification subsystems are all connected to the instrument to be verified and the reference instrument group and are capable of sending an instrument synchronous control and status setup to collect different verification items and verification status and to automatically analyze different item status and indicators of the instrument to be verified. The five verification subsystems are configured to independently complete a corresponding verification item to output a corresponding verification report.

In some embodiments, the automatic verification system is configured to select a subsystem corresponding to the instrument to be verified to execute corresponding detection items, and select a reference instrument corresponding to the instrument to be verified from the reference instrument group and enable switching to a corresponding detection path, so as to achieve synchronous continuous control and complete data record and collection of detection items of the instrument to be verified to output a verification report.

In some embodiments, the reference instrument group comprises a reference power meter, a reference local oscillation signal source, a reference spectrum analyzer, a reference microwave transformer, a reference noise source, a reference measuring receiver and a reference frequency meter.

In some embodiments, the communication control interface comprises a reference interface adapter, a USB/general purpose interface bus (GPIB) interface and a network interface; the reference interface adapter is configured to connect the instrument to be verified with a corresponding reference instrument of the reference instrument group to achieve control and collection of the instrument to be verified; and the USB/GPM interface and the network interface are both configured to receive a command from an external control system to complete switch and transfer of a control signal and a detection signal. The intelligent instrument verification system is configured to switch between different test interfaces of the reference interface adapter in accordance with different instruments to be verified and verification items. Specifically, the intelligent instrument verification system is configured to select a verification object and match a verification item, according to a corresponding verification method to integrate a verification Test ProgramSet (TPS), automatically switch and select a reference instrument and the reference interface adapter to automatically match the verification object. The communication control interface is in bidirectional communication with the intelligent instrument verification system to enable the input of control signal and the exchange of measurement data and status data, and the command switch and data exchange with the reference instrument group.

In some embodiments, the reference interface adapter comprises a standard matrix switch, a standard power divider and a standard attenuator; the standard matrix switch is configured to be connected to different external reference signals or external reference instruments during verification, and configured to enable automatic switching and selection among the external reference signals or external reference instruments according to a preset rule; the standard power divider is configured to enable a standard power division of the detection signal under different verification modes, so as to complete a specific detection item; and the standard attenuator is configured to attenuate the reference signals to complete different verification items.

In a second aspect, this application provides method for verifying an instrument using the above-mentioned intelligent instrument verification system, comprising:

(S1) warming the intelligent instrument verification system up;

(S2) operating the automatic verification system; and selecting a test program corresponding to the instrument to be verified;

(S3) executing the test program; and displaying status and data of the instrument to be verified and a corresponding reference instrument in the reference instrument group in real time; and

(S4) performing synchronous control and data collection on the instrument to be verified and the corresponding reference instrument; performing formatting analysis on collected data; and outputting a verification report after completing the test program.

Compared to the prior art, the disclosure has the following beneficial effects.

(1) Strong Universality

The intelligent instrument verification system provided herein enables the universal verification of general instruments.

(2) Excellent Portability

For different types of instruments, a corresponding verification test program set can be established by making some simple modifications to the verification item.

(3) High Verification Efficiency

Furthermore, the intelligent instrument verification system is capable of automatically verifying different instruments and automatically generating a verification report.

### BRIEF DESCRIPTION OF THE DRAWINGS

FIG. 1 is a block diagram of an intelligent instrument verification system in accordance with an embodiment of the disclosure;

FIG. 2 is a block diagram of a reference instrument group in accordance with an embodiment of the disclosure;

FIG. 3 is a block diagram of a communication control interface in accordance with an embodiment of the disclosure;

FIG. 4 is a block diagram of a reference interface adapter in accordance with an embodiment of the disclosure;

FIG. 5 is a workflow chart of the intelligent instrument verification system in accordance with an embodiment of the disclosure;

FIG. 6 is a verification flow chart of a signal generator verification subsystem in accordance with an embodiment of the disclosure;

FIG. 7 is a verification flow chart of a noise-measuring instrument verification subsystem in accordance with an embodiment of the disclosure;

FIG. 8 is a verification flow chart of a spectrum analyzer verification subsystem in accordance with an embodiment of the disclosure;

FIG. 9 is a verification flow chart of a power meter verification subsystem in accordance with an embodiment of the disclosure; and

FIG. 10 is a verification flow chart of a network analyzer verification subsystem in accordance with an embodiment of the disclosure.

### DETAILED DESCRIPTION OF EMBODIMENTS

The disclosure will be described in detail below with reference to accompanying drawings and embodiments. The following embodiments are merely illustrative of the present disclosure, and are not intended to limit the disclosure.

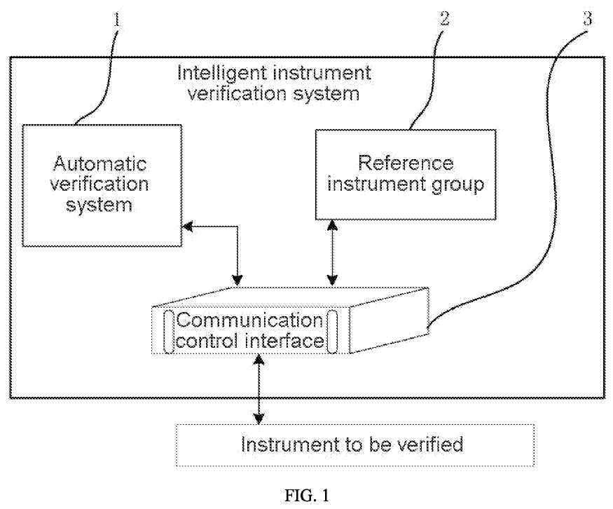

Referring to FIG. 1, an intelligent instrument verification system includes an automatic verification system 1, a reference instrument group 2 and a communication control interface 3. The automatic verification system 1 is in bidirectional communication with an instrument to be verified through the communication control interface 3. The automatic verification system 1 is in bidirectional communication with the reference instrument group 2 through the communication control interface 3. The reference instrument group 2 is in bidirectional communication with the instrument to be verified through the communication control interface 3.

The initialization of the reference instrument group 2 and the communication control interface 3 is enabled through the communication between the automatic verification system 1 and interfaces of the communication control interface 3. According to a verification process corresponding to the instrument to be verified, the selection and access of a test interface and the selection and control of a corresponding reference instrument in the reference instrument group 2 are performed. During the operation, the intelligent instrument verification system automatically performs the verification of corresponding items. The automatic verification system 1 is configured to automatically collect setting and measurement data of the reference instrument group 2 and the instrument to be verified, analyze the collected data and perform formatted output of the data to generate a verification report.

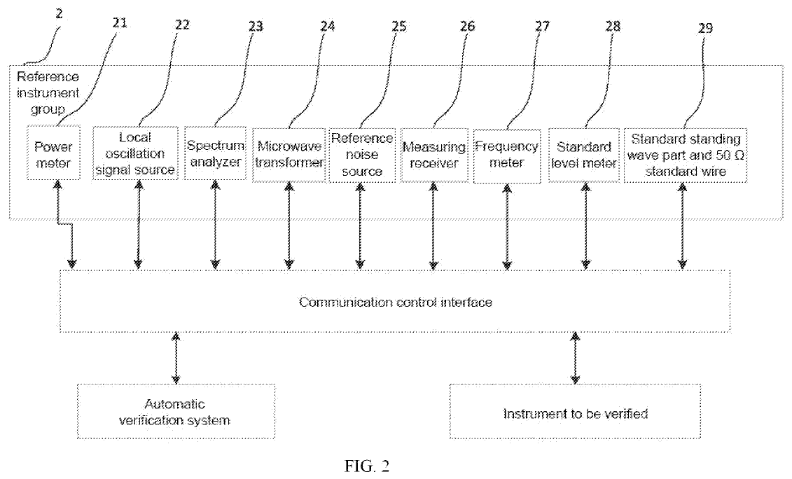

Referring to FIG. 2, the reference instrument group 2 includes a power meter 21, a local oscillation signal source 22, a spectrum analyzer 23, a microwave transformer 24, a reference noise source 25, a measuring receiver 26, a frequency meter 27, a standard level meter 28 and a 50Ω standard wire 29, which are in bidirectional communication with the automatic verification system 1 through the communication control interface 3.

During the operation, by selecting a subsystem to be verified, the automatic verification system 1 automatically selects and controls the corresponding reference instrument of the reference instrument group 2 according to the verification test program set (TPS) to perform automatic control and data reading. For example, when a power meter verification subsystem is selected and operated, the automatic verification system 1 is connected to the power meter 21, the local oscillation signal source 22 and a standard power divider 312 of the reference instrument group 2 through a reference interface adapter 31 of the communication control interface 3, so as to achieve the automatic verification.

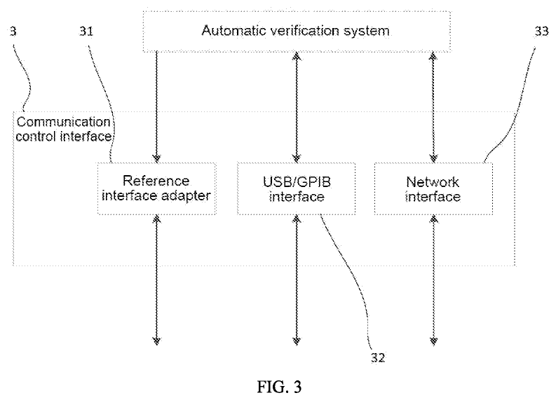

Referring to FIG. 3, the communication control interface 3 includes the reference interface adapter 31, a USB/GPIB interface 32 and a network interface 33. The reference interface adapter 31 is a physical interface for direct signal switching and transmission between the instrument to be verified and the reference instrument group 2. A control command of a signal is sent by the automatic verification system 1. According to the verification requirement, the direct signal switching and transmission between the instrument to be verified and the reference instrument group 2 can be completed under a control of the automatic verification system 1.

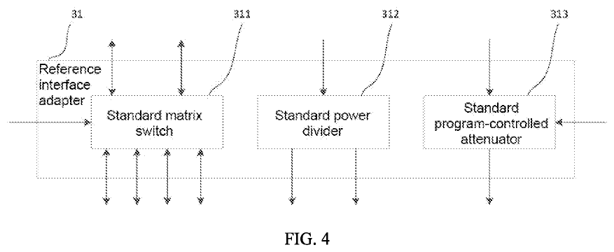

Referring to FIG. 4, the reference interface adapter 31 includes a standard matrix switch 311, the standard power divider 312 and a standard program-controlled attenuator 313. By means of the verification TPS, the standard matrix switch 311 enables the direct signal switching and transmission between the instrument to be verified and the reference instrument group 2 under control of the automatic verification system 1. The standard power divider 312 enables the standard power division according to certain verification requirements. The standard attenuator 313 enables the setup of verification items under control of the automatic verification system 1. For example, when operating a signal generator verification subsystem of the automatic verification system 1, the standard matrix switch 311 is connected to the power meter 21, the local oscillation signal source 22, the spectrum analyzer 23, the microwave transformer 24, the measuring receiver 26 and the frequency meter 27. According to different verification items and process rules, the sequential switching and selective connection of different test points of a tested signal unit is achieved. Switching and operation rules of a noise-measuring instrument verification subsystem, a spectrum analyzer verification subsystem, a power meter verification subsystem and a network analyzer verification subsystem are similar to those of the signal generator verification subsystem, and the differences merely lie in the selection of the reference instrument, verification item and verification method.

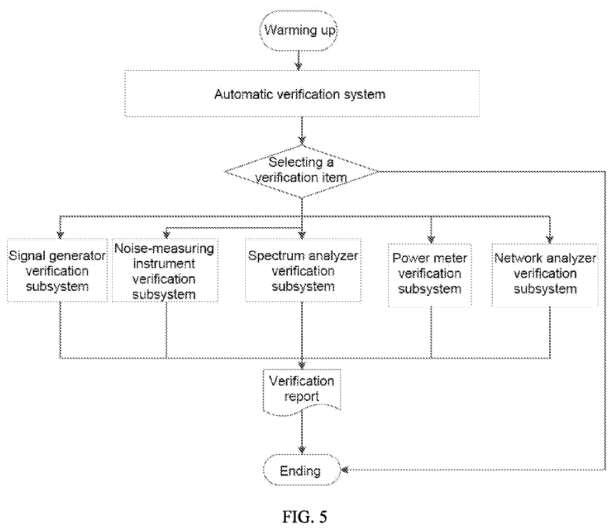

Referring to FIG. 5, during operating, the intelligent instrument verification system is warmed up. The automatic verification system 1 is operated. A test program is selected corresponding to the instrument to be verified. The test program is executed by the intelligent instrument verification system. Status and data of the instrument to be verified and the reference instrument group 2 are displayed in the intelligent instrument verification system in real time. The synchronous control and data collection are performed on the instrument to be verified and the reference instrument group 2, and the collected data is subjected to formatting analysis. A verification report is output after the test program is completed.

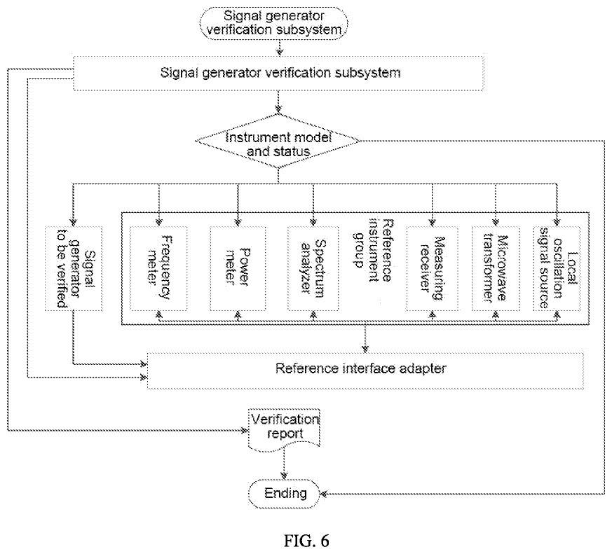

Referring to FIG. 6, the signal generator verification subsystem is configured for the automatic verification and test of a signal source. During the operation, the model and status of a signal generator to be verified are detected. According to the model and status of the signal generator to be verified, a corresponding verification program is called. Under the corresponding test control, the standard matrix switch 311 is controlled to be sequentially switched to be connected with reference instruments of the reference instrument group 2. When switched to be connected with the frequency meter 27, the verification of frequency accuracy is achieved; when switched to the power meter 21, the verification of level accuracy is achieved; when switched to the spectrum analyzer 23, the verification of harmonic suppression and phase noise is achieved. When switched to the measuring receiver 26, the microwave transformer 24 and the local oscillation signal source 22, the verification of residual amplitude and frequency modulation of the carrier wave, the verification of amplitude modulation accuracy, the verification of frequency bias accuracy and the verification of phase bias accuracy are achieved. After the test of verification items is completed, a verification report is automatically output. During the verification of frequency accuracy, the automatic verification system 1 controls the reference interface adapter 31 through a USB interface and is connected to the frequency meter 27. The automatic verification system 1 is connected to the signal generator to be verified and the frequency meter 27 through the USB/GPIB interface 32 and the network interface 33 for synchronous control and collection, so as to achieve the measurement and verification of level accuracy.

During the verification of harmonic suppression and phase noise, the automatic verification system 1 controls the reference interface adapter 31 through the USB interface and is connected to the spectrum analyzer 23. The automatic verification system 1 is connected to the signal generator to be verified and the spectrum analyzer 23 through the USB/GPIB interface 32 and the network interface 33 for a synchronous control and collection, so as to achieve a measurement and the verification of harmonic suppression and verification of phase noise.

During the verification of residual amplitude and frequency modulation of the carrier wave, the verification of amplitude modulation accuracy, the verification of frequency bias accuracy of frequency modulation and the verification of phase bias accuracy of phase modulation, the automatic verification system 1 controls the reference interface adapter 31 through a USB interface and is connected to the measuring receiver 26, microwave transformer 24 and the signal generator to be verified for a synchronous control and collection, so as to achieve the verification of residual amplitude and frequency modulation of the carrier wave, the verification of amplitude modulation accuracy, the verification of frequency bias accuracy of frequency modulation and the verification of phase bias accuracy of phase modulation and then output a verification report.

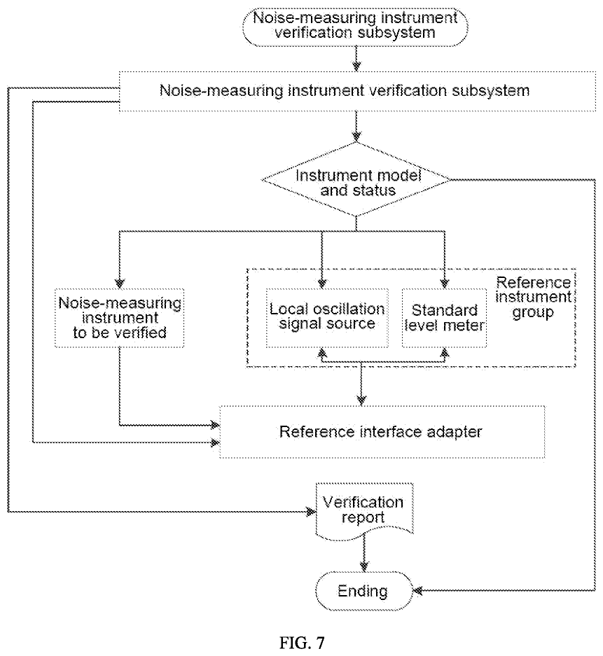

Referring to FIG. 7, the noise-measuring instrument verification subsystem is configured to automatically verify a noise-measuring instrument. When operating the intelligent instrument verification system, a model and status of a verified noise-measuring instrument are tested. According to the model and status of the verified noise-measuring instrument, a corresponding verification program is called. Under control of the corresponding verification program, the reference instruments of the reference instrument group 2 are sequentially switched to achieve a verification of the noise-measuring instrument, such as frequency width and F-degree dial accuracy.

During the verification of the noise-measuring instrument, the automatic verification system 1 controls the reference interface adapter 31 through the USB interface and is connected to the local oscillation signal source 22 and the standard level meter 28. The automatic verification system 1 is connected to the local oscillation signal source 22, the standard attenuator 313 and the standard level meter 28 through the USB/GPIB interface 32 and the network interface 33 for a synchronous control and collection, such that a measurement and verification of a minimum rated input level, gain adjustment range, frequency width, and F-degree dial accuracy of the noise-measuring instrument are achieved. After verification, a verification report is output.

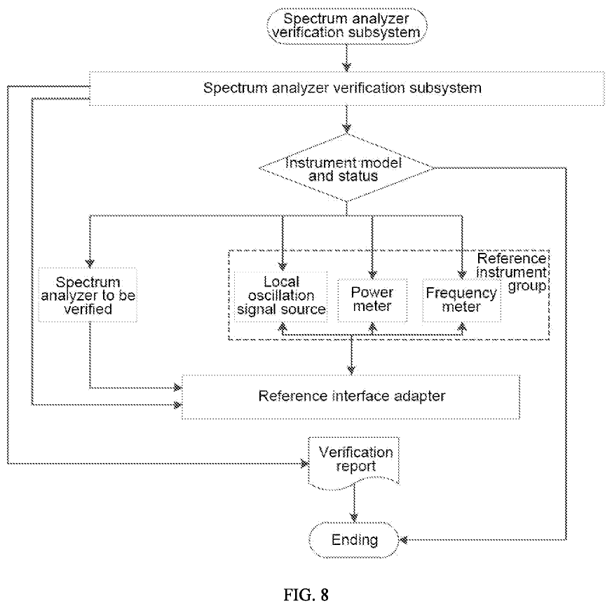

Referring to FIG. 8, the spectrum analyzer verification subsystem is configured to automatically verify a spectrum analyzer. When operating the intelligent instrument verification system, a model and status of a verified spectrum analyzer are tested. According to the model and status of the verified spectrum analyzer, a corresponding verification program is called. Under control of the corresponding verification program, the corresponding reference instrument of the reference instrument group 2 is connected.

The local oscillation signal source 22, the power meter 21, the standard matrix switch 311, the standard power divider 312 and the standard attenuator 313 are selected to be connected for the verification of signal calibration, input attenuation, sweep width, resolution bandwidth, etc. After verification, a verification report is output.

During the verification of verification signal, input attenuation, sweep width, resolution bandwidth, etc., the automatic verification system 1 controls the reference interface adapter 31 through the USB interface and is connected to the spectrum analyzer and the reference instrument group 2 through the USB/GPIB interface 32 and the network interface 33. The local oscillation signal source 22, the power meter 21, the standard matrix switch 311, the standard power divider 312 and the standard attenuator 313 are controlled for a synchronous control and collection, so as to achieve the verification of verification signal, input attenuation, sweep width, resolution bandwidth, etc. After verification, the verification report is output.

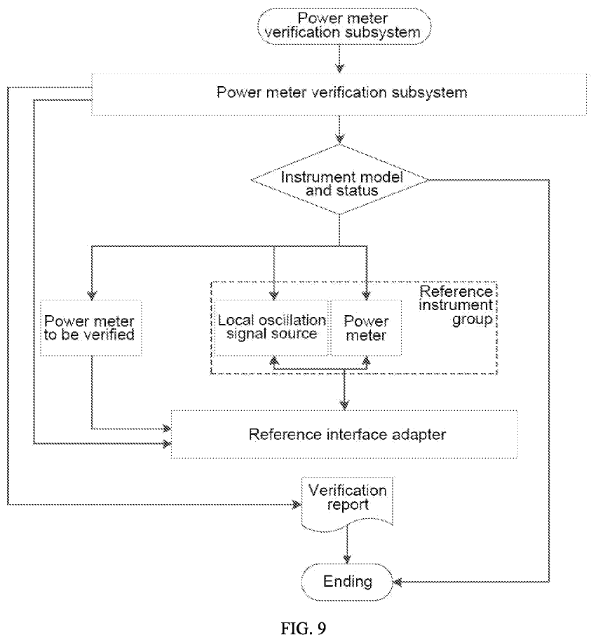

Referring to FIG. 9, the power meter verification subsystem is configured to automatically verify a power meter. When operating the intelligent instrument verification system, a model and status of a verified power meter are tested. According to the model and status of the verified noise-measuring instrument, a corresponding verification program is called.

During a verification of range accuracy and frequency response of the power meter, the automatic verification system 1 is connected to the power meter 21, the local oscillation signal source 22 and the standard power divider 312 through the USB/GPM interface 32 and the network interface 33. The power meter and the local oscillation signal source 22 is controlled to automatically switch the automatic verification system 1 to the standard power divider 312 and the power meter 21 for a synchronous control and collection, so as to achieve a measurement and verification of range accuracy and frequency response. After verification, a verification report is output.

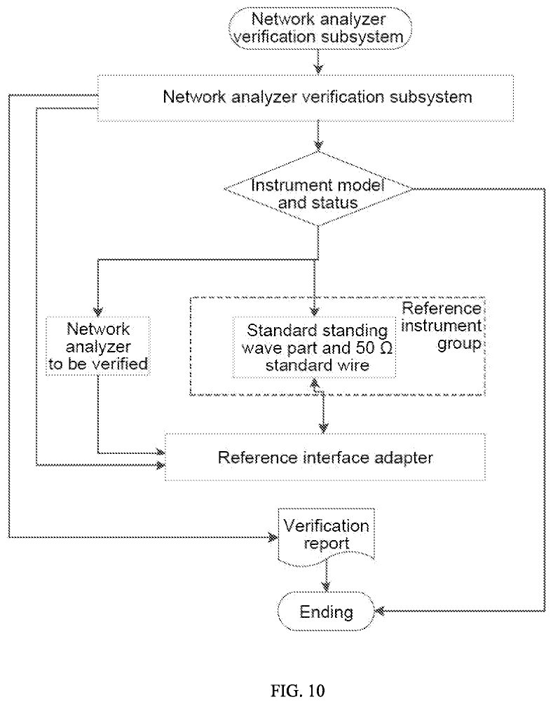

Referring to FIG. 10, the network analyzer verification subsystem is configured to automatically verify a network analyzer. When operating the intelligent instrument verification system, a model and status of a signal generator to be verified are tested. According to the model and status of the signal generator to be verified, a corresponding verification program is called. Under control of the corresponding verification program, the reference instruments of the reference instrument group 2 are sequentially switched to.

During a verification of voltage standing wave ratio, attenuation and transmission phase shift of the network analyzer, the automatic verification system 1 controls the network analyzer through the USB/GPM interface 32 and selects the USB/GPM interface 32. By means of the standard matrix switch 311, the standard power divider 312 and the standard attenuator 313, the automatic verification system 1 is connected to the standard standing wave part and 50Ω standard wire 29 for a control and collection of the network analyzer, so as to achieve a measurement and the verification of voltage standing wave ratio, attenuation and transmission phase shift. After verification, a verification report is output.

A process of verification in this embodiment is further described with reference to FIGS. 1-10.

During verification, the instrument to be verified is connected to the communication control interface 3, including a stored program control connection (GPIB interface or network interface). A signal input (or output) port is connected to the communication control interface 3. The intelligent instrument verification system is warmed up, then the automatic verification system 1 is operated. The automatic verification system 1 is subjected to initialization to call a verification program according to a model. The instrument to be verified, the communication control interface 3 and the reference instruments are subjected to initialization options and setup. A verification subsystem of the automatic verification system 1 is operated to automatically verify the instrument to be verified. The verification items are executed one by one through a synchronous control and collection of the communication control interface 3 and the reference instruments. A measurement data is displayed and recorded synchronously and an abnormal non-conforming item will be exceptionally highlighted. Furthermore, the intelligent instrument verification system is capable of performing database storage and call. A formatted verification report will be automatically generated based on the measurement data. If necessary, a historical verification report can be output for comparative analysis of the instrument status.

The subsystems can automatically identify corresponding instruments, and automatically control the instrument to be verified, the communication control interface 3 and the reference instrument group 2. Moreover, the subsystems can also automatically collect the measurement data, store the verification data, call the calibration data, perform data analysis and output a verification report, enabling the efficient, accurate and intelligent verification.

In summary, the intelligent instrument verification system in this embodiment integrates the reference instrument group with various program-controlled ports, communication control interface and verification methods, which enables the automatic instrument verification, so as to greatly improve the efficiency of instrument verification and data analysis.

Described above are merely illustrative of the disclosure, and are not intended to limit the disclosure. Although the disclosure has been illustrated and described in detail above, it should be understood that those skilled in the art could still make modifications and changes to the embodiments of the disclosure. Those modifications, changes, replacements and variations made by those skilled in the art based on the content disclosed herein without departing from the scope of the disclosure shall fall within the scope of the present disclosure defined by the appended claims.

What is claimed is:

1. An intelligent instrument verification system, comprising:
an automatic verification system;
a reference instrument group; and
a communication control interface;
wherein the automatic verification system is connected to an instrument to be verified through the communication control interface; the automatic verification system is connected to the reference instrument group through the communication control interface; and the reference instrument group is connected to the instrument to be verified through the communication control interface;
the communication control interface comprises a reference interface adapter, a USB/general purpose interface bus (GPIB) interface and a network interface; the reference interface adapter is configured to connect the instrument to be verified with a corresponding reference instrument of the reference instrument group to achieve control and collection of the instrument to be verified; and the USB/GPM interface and the network interface are both configured to receive a command from an external control system to complete switch and transfer of a control signal and a detection signal; and
the reference interface adapter comprises a standard matrix switch, a standard power divider and a standard attenuator; the standard matrix switch is configured to be connected to different external reference signals or external reference instruments during verification, and configured to enable automatic switching and selection among the external reference signals or external reference instruments according to a preset rule; the standard power divider is configured to enable a standard power division of the detection signal under different verification modes, so as to complete a specific detection item; and the standard attenuator is configured to attenuate the reference signals to complete different verification items.

2. The intelligent instrument verification system of claim 1, wherein the automatic verification system comprises a first verification subsystem, a second verification subsystem, a third subsystem, a fourth verification subsystem and a fifth verification subsystem; the first verification subsystem is configured to verify a signal generator; the second verification subsystem is configured to verify a noise-measuring instrument; the third verification subsystem is configured to verify a spectrum analyzer; the fourth verification subsystem is configured to verify a power meter; and the fifth verification subsystem is configured to verify a network analyzer.

3. The intelligent instrument verification system of claim 2, wherein the automatic verification system is configured to select a subsystem corresponding to the instrument to be verified to execute corresponding detection items, and select a reference instrument corresponding to the instrument to be verified from the reference instrument group and enable switching to a corresponding detection path, so as to achieve synchronous continuous control and complete data record and collection of detection items of the instrument to be verified to output a verification report.

4. The intelligent instrument verification system of claim 3, wherein the reference instrument group comprises a reference power meter, a reference local oscillation signal source, a reference spectrum analyzer, a reference microwave transformer, a reference noise source, a reference measuring receiver and a reference frequency meter.

5. A method for verifying an instrument using the intelligent instrument verification system of claim 1, comprising:
(S1) warming the intelligent instrument verification system up;
(S2) operating the automatic verification system; and selecting a test program corresponding to the instrument to be verified;
(S3) executing the test program; and displaying status and data of the instrument to be verified and a corresponding reference instrument in the reference instrument group in real time; and
(S4) performing synchronous control and data collection on the instrument to be verified and the corresponding reference instrument; performing formatting analysis on collected data; and outputting a verification report after completing the test program.
